(19) United States
(12) Patent Application Publication
(10) Pub. No.: US 2026/0113029 A1
(43) Pub. Date: Apr. 23, 2026

(54) HOT SWAP CONTROLLER CIRCUIT AND CIRCUIT SYSTEM

(71) Applicant: ROHM CO., LTD., Kyoto (JP)

(72) Inventors: Tadayuki SAKAMOTO, Kyoto (JP); Daichi NAKAJIMA, Kyoto (JP)

(21) Appl. No.: 19/355,067

(22) Filed: Oct. 10, 2025

(30) Foreign Application Priority Data
Oct. 17, 2024 (JP) 2024-182099

(51) Int. Cl. H03K 17/56

(52) U.S. Cl. CPC H03K 17/56

(57) ABSTRACT

A hot swap controller circuit that controls a plurality of transistors connected in parallel, includes: a first gate terminal to be connected to a gate of a first transistor having a widest safe operation area among the plurality of transistors; a second gate terminal to be connected to a gate of a second transistor other than the first transistor among the plurality of transistors; and a gate controller configured to control a voltage of the first gate terminal and a voltage of the second gate terminal, wherein, when the plurality of transistors are turned on, the gate controller controls the voltage of the first gate terminal and the voltage of the second gate terminal so that the first transistor is turned on before the second transistor is turned on.

### CROSS-REFERENCE TO RELATED APPLICATION

The present invention claims priority under 35 U.S.C. § 119 to Japanese Patent Application No. 2024-182099, filed on Oct. 17, 2024, the entire contents of which are incorporated herein by reference.

### TECHNICAL FIELD

The present disclosure relates to a hot swap controller circuit and a circuit system.

### BACKGROUND

In a system such as a server, when there is a need to replace a module or board, a hot swap controller circuit (IC) is used to perform hot swapping, which allows attachment and detachment of the module that needs to be replaced without shutting down the system by powering the system off.

In recent years, power consumption of modules and boards has increased due to the increased performance of servers. For this reason, a configuration is adopted in which a plurality of discrete transistors (switches) used together with the hot swap controller circuit are arranged in parallel to reduce an on-resistance.

### BRIEF DESCRIPTION OF DRAWINGS

The accompanying drawings, which are incorporated in and constitute a part of the specification, illustrate embodiments of the present disclosure.

FIG. 1 is a circuit diagram of a circuit system including a hot swap controller IC according to an embodiment of the present disclosure.

FIG. 2 is a diagram for explaining an operation of the hot swap controller IC of FIG. 1.

FIG. 3 is a circuit diagram of a circuit system including a hot swap controller IC according to a comparative technique.

FIG. 4 is a diagram for explaining an operation of the hot swap controller IC of FIG. 3.

FIG. 5 is a circuit diagram of a circuit system including a hot swap controller IC according to an example.

FIG. 6 is a waveform diagram for explaining an operation of the hot swap controller IC of FIG. 5.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Overview of Embodiment

An overview of some exemplary embodiments of the present disclosure will be described. This overview describes, in a simplified form, some concepts of one or more embodiments, as a prologue to detailed description which will be presented later, and for the purpose of basic understanding of the embodiments, but it is not intended to limit the scope of the disclosure. This overview is not a comprehensive overview of all possible embodiments, and it is intended to neither identify key elements of all embodiments nor delineate the scope of some or all aspects. For the sake of convenience, “an embodiment” may be used to refer to one embodiment (example or modification) or a plurality of embodiments (examples or modifications) described in the present disclosure.

A hot swap controller circuit according to one embodiment of the present disclosure controls a plurality of transistors connected in parallel. The hot swap controller circuit includes: a first gate terminal to be connected to a gate of a first transistor having the widest safe operation area (SOA) among the plurality of transistors; a second gate terminal to be connected to a gate of a second transistor other than the first transistor among the plurality of transistors; and a gate controller configured to control a voltage of the first gate terminal and a voltage of the second gate terminal. When the plurality of transistors are turned on, the gate controller controls the voltage of the first gate terminal and the voltage of the second gate terminal so that the first transistor is turned on before the second transistor is turned on. In other words, the gate controller raises the voltage of the second gate terminal with a delay relative to the voltage of the first gate terminal. Further, in other words, the gate controller raises the voltage of the second gate terminal while keeping the same lower than the voltage of the first gate terminal when turning on the plurality of transistors.

According this configuration, since the voltage of the first gate terminal rises prior to the voltage of the second gate terminal, among the plurality of transistors, a gate-source voltage of the first transistor is higher than a gate-source voltage of the second transistor. Therefore, since a current is concentrated in the first transistor, it is sufficient to select a component with a wide SOA for the first transistor, and an inexpensive component with a narrow SOA may be selected for the remaining second transistor. This reduces a cost of the system.

In one embodiment of the present disclosure, the gate controller may increase the voltage of the first gate terminal and the voltage of the second gate terminal while keeping a potential difference therebetween constant.

In one embodiment, the gate controller may include: a control circuit configured to generate a control signal; a gate driver configured to generate a first gate voltage at the first gate terminal in response to the control signal; and a constant voltage circuit connected between the first gate terminal and the second gate terminal. This causes the voltage of the second gate terminal to increase with a delay relative to the voltage of the first gate terminal. Since a gate driver configured to generate a second gate voltage is not required, a circuit area is reduced.

In one embodiment, the constant voltage circuit may include one diode or a plurality of diodes connected in series. A potential difference between the first gate terminal and the second gate terminal can be set according to the number of diodes.

In one embodiment, the control circuit may generate the control signal so that a current flowing through the plurality of transistors is a target amount.

In one embodiment, the control circuit may generate the control signal so that power consumption of the plurality of transistors is a target amount.

In one embodiment, the control circuit may generate the control signal so that the first gate voltage changes according to a predetermined waveform.

In one embodiment, the gate controller may include: a voltage detection circuit configured to assert a gate detection signal when the gate-source voltage of the first transistor exceeds a predetermined threshold voltage; and a switch connected between the first gate terminal and the second gate terminal. The control circuit may turn on the switch when the gate detection signal is asserted.

In one embodiment, the hot swap controller circuit may be integrated on a single semiconductor substrate. The term “integrated” includes a case where all components of a circuit are formed on a semiconductor substrate and a case where main components of a circuit are integrated, and some resistors, capacitors, etc. may be provided outside the semiconductor substrate for adjusting circuit constants. By integrating the circuit on a single chip, the circuit area can be reduced and characteristics of the circuit elements can be kept uniform.

A circuit system according to one embodiment includes: a plurality of transistors connected in parallel; and any one of the above-described hot swap controller circuits configured to control the plurality of transistors.

A circuit system according to one embodiment of the present disclosure includes: a first transistor connected between an input terminal and an output terminal and having a first safe operation area; at least one second transistor connected in parallel with the first transistor between the input terminal and the output terminal and having a second safe operation area narrower than the first safe operation area; and a hot swap controller circuit configured to control the first transistor and the at least one second transistor. The hot swap controller circuit turns on the at least one second transistor after the first transistor is turned on.

### Embodiments

Preferred embodiments will be now described with reference to the drawings. Like or equivalent components, members, and processes illustrated in the respective drawings are given like reference numerals and a repeated description thereof will be properly omitted. Further, the embodiments are presented by way of example only and are not intended to limit the present disclosure, and all features or combination thereof described in the embodiments may not be essential to the present disclosure.

In the present disclosure, “a state where a member A is connected to a member B” includes not only a case where the member A and the member B are physically directly connected, but also a case where the member A and the member B are indirectly connected via any other member that does not substantially affect an electrical connection state between the members A and B or does not impair functions and effects achieved by combinations of the members A and B.

Similarly, “a state where a member C is connected (installed) between a member A and a member B” includes not only a case where the member A and the member C or the member B and the member C are directly connected, but also a case where the member A and the member C or the member B and the member C are indirectly connected via any other member that does not substantially affect an electrical connection state between the members A and C or the members B and C or does not impair functions and effects achieved by combinations of the members A and C or the members B and C.

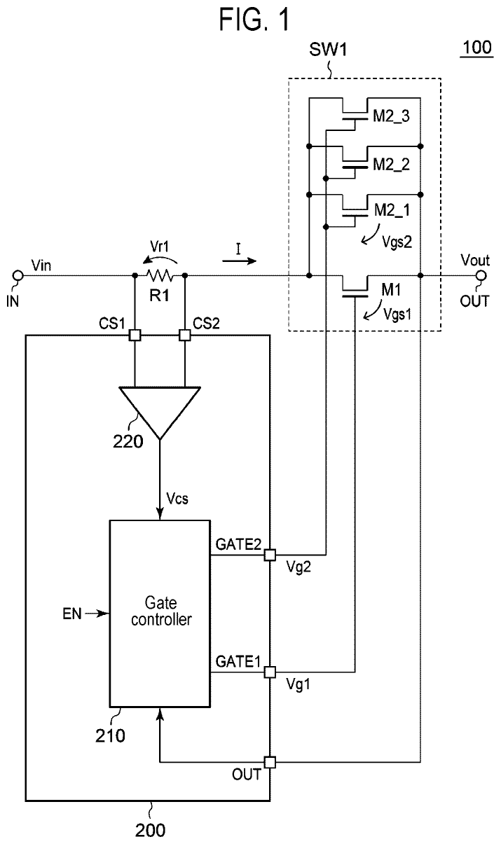

FIG. 1 is a circuit diagram of a circuit system 100 including a hot swap controller IC 200 according to an embodiment of the present disclosure. The circuit system 100 includes a switch SW1, a sense resistor R1, and a hot swap controller IC (Integrated Circuit) 200.

The sense resistor R1 and the switch SW1 are connected in series between an input node IN and an output node OUT. The input node IN is supplied with an input voltage Vin. The switch SW1 includes a first transistor M1 and second transistors M2_1 to M2_3 connected in parallel. These transistors M1 and M2_1 to M2_3 are discrete components. The first transistor M1 has the widest safe operation area (SOA), and the remaining second transistors M2_1 to M2_3 have SOAs narrower than that of the first transistor M1.

A voltage drop Vr1 proportional to a current I flowing through the switch SW1 occurs in the sense resistor R1.

The hot swap controller IC 200 is an IC configured to control the switch SW1.

The hot swap controller IC 200 includes a first gate terminal GATE1, a second gate terminal GATE2, an output terminal OUT, current detection terminals CS1 and CS2, a gate controller 210, and a current sense amplifier 220. The first gate terminal GATE1 is connected to the gate of the first transistor M1, which has the widest safe operation area, among the plurality of transistors M1 and M2_1 to M2_3 constituting the switch SW1. The second gate terminal GATE2 is connected to the gates of the remaining second transistors M2_1 to M2_3.

The gate controller 210 controls a voltage Vg1 of the first gate terminal GATE1 and a voltage Vg2 of the second gate terminal GATE2 to control an on/off state of the switch SW1.

An enable signal EN that instructs the on/off of the switch SW1 is input to the gate controller 210. The gate controller 210 turns off the switch SW1 when the enable signal EN is negated (e.g., at a low level), and turns on the switch SW1 when the enable signal EN is asserted (e.g., at a high level).

When the enable signal EN is asserted, the gate controller 210 increases the voltage (referred to as a second gate voltage) Vg2 of the second gate terminal GATE2 with a delay relative to the voltage (referred to as a first gate voltage) Vg1 of the first gate terminal GATE1.

The gate controller 210 may increase the first gate voltage Vg1 and the second gate voltage Vg2 while keeping a potential difference ΔV therebetween constant.

When a gate-source voltage Vgs1 of the first transistor M1, i.e., a potential difference between the first gate voltage Vg1 and an output voltage Vout, reaches a predetermined threshold value, the gate controller 210 may set the second gate voltage Vg2 to the same voltage level as the first gate voltage Vg1.

The current detection terminals CS1 and CS2 are connected to both ends of the sense resistor R1. The current sense amplifier 220 amplifies the voltage drop Vr1 of the sense resistor R1 to generate a current detection signal Vcs. The current detection signal Vcs indicates the current I flowing through the switch SW1.

The gate controller 210 may adjust the voltage levels of the gate voltages Vg1 and Vg2 according to the current detection signal Vcs. For example, the gate controller 210 may perform overcurrent protection or power limitation based on the current detection signal Vcs.

The above is a configuration of the hot swap controller IC 200. Next, its operation will be described.

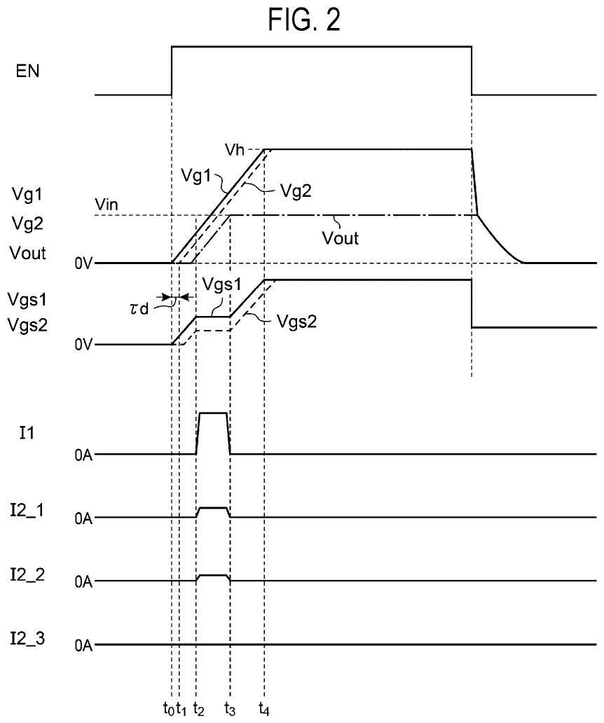

FIG. 2 is a diagram for explaining an operation of the hot swap controller IC 200 of FIG. 1. Before time t₀, the enable signal EN is at a low level, the switch SW1 is in an off state, and the output voltage Vout is 0 V.

When the enable signal EN transitions to a high level at time t₀, the gate controller 210 starts to increase the first gate voltage Vg1. At time t₁, which is delayed by a time τd therefrom, the gate controller 210 starts to increase the second gate voltage Vg2.

The gate-source voltage Vgs1 of the first transistor M1 is Vg1-Vout, and the gate-source voltage Vgs2 of each of the second transistors M2_1 to M2_3 is Vg2-Vout.

When the gate-source voltage Vgs1 of the first transistor M1 exceeds the gate threshold voltage Vgs(th) of the first transistor M1 at time t₂, the first transistor M1 turns on, a current I1 flows through the first transistor M1, a load (for example, a smoothing capacitor) on the side of the output node OUT is charged, and the output voltage Vout begins to rise.

When the gate-source voltage Vgs2 of each of the second transistors M2_1 to M2_3 exceeds the gate threshold voltage Vgs(th), the second transistors M2_1 to M2_3 also turn on and currents I2_1 to I2_3 flow through the second transistors M2_1 to M2_3, respectively.

When the output voltage Vout rises close to the input voltage Vin at time t₃, the currents flowing through the first transistor M1 and the second transistors M2_1 to M2_3 become zero.

Then, at time t₄, the gate voltage Vg1 of the first transistor M1 reaches a high voltage Vh, and subsequently the gate voltage Vg2 of the second transistor M2 reaches the high voltage Vh.

The above is the operation of the circuit system 100 according to the embodiment. In this embodiment, since the gate voltage Vg1 of the first transistor M1 rises before the gate voltage Vg2 of the second transistor M2 rises, a relationship of Vgs1>Vgs2 holds. Therefore, since a current is concentrated in the first transistor M1, the currents I2_1 to I2_3 of the second transistors M2_1 to M2_3 are relatively smaller than the current I1 of the first transistor M1.

Therefore, it is sufficient to select an element with a large SOA for the first transistor M1, and elements with small SOAs may be selected for the remaining second transistors M2_1-M2_3, which turn on with a delay.

Advantages of the hot swap controller IC 200 become clear when compared with a comparative technique. Therefore, a hot swap controller IC 200R according to the comparative technique will be described focusing on the differences from the hot swap controller IC 200 according to the embodiment.

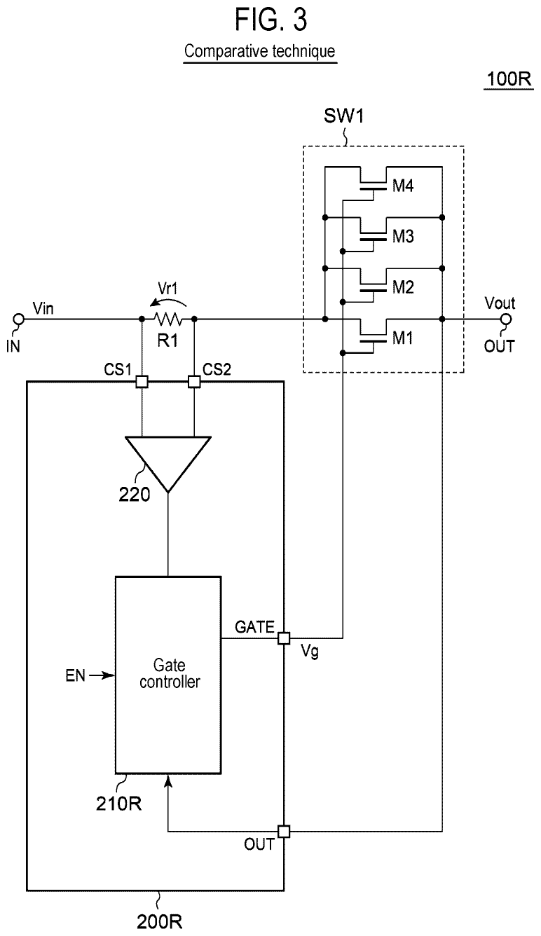

FIG. 3 is a circuit diagram of a circuit system 100R including a hot swap controller IC 200R according to the comparative technique. In the comparative technique, a switch SW1 includes a plurality of transistors M1 to M4 with a same SOA. The gates of the plurality of transistors M1 to M4 are connected in common to a single gate terminal GATE of the hot swap controller IC 200R.

A gate controller 210R controls the voltage Vg of the gate terminal GATE to control the on/off state of the switch SW1. Specifically, the gate controller 210R increases the gate voltage Vg when the enable signal EN is asserted.

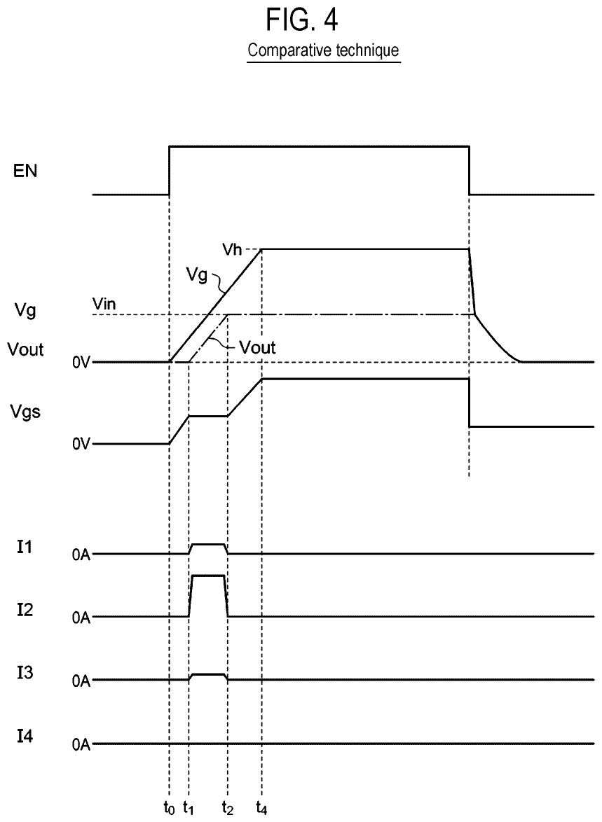

FIG. 4 is a diagram for explaining an operation of the hot swap controller IC 200R of FIG. 3. Before time t₀, the enable signal EN is at a low level, the switch SW1 is in an off state, and the output voltage Vout is 0 V.

When the enable signal EN transitions to a high level at time t₀, the gate controller 210R starts to increase the gate voltage Vg.

At time t₂, the gate-source voltage Vgs of the transistors M1 to M4 rises close to the threshold voltage Vgs(th), and the transistors M1 to M4 turn on. In the comparison technique, the gate-source voltages Vgs of all the transistors M1 to M4 are equal. The plurality of transistors M1 to M4 are same devices with the same SOA, but the threshold voltage Vgs(th) can take different values due to manufacturing variations. Therefore, among the plurality of transistors M1 to M4, a relatively large current flows through one with a small threshold voltage Vgs(th), and a relatively small current flows through one with a high threshold voltage Vgs(th). In the example of FIG. 4, the threshold voltage Vgs(th) is smallest for M2, increasing in the order of M1, M3, and M4, and a current flows through M2, M1, M3, and M4 such that it increases in this order.

Since the currents flowing through the transistors M1 to M4 depend on the variation in the threshold voltage Vgs(th), it is not known which transistor a large current flows through. In other words, there is a possibility that a large current will flow through any transistor. Therefore, in the comparative technique, it is necessary to select an element with a large SOA for all of the transistors M1 to M4. This results in high costs.

As described above, in the embodiment, since it is determined that the gate-source voltage Vgs1 of the first transistor M1 is larger than the gate-source voltage Vgs2 of the second transistor M2, an element with a large SOA is selected only for the first transistor M1, and elements with small SOAs may be selected for the remaining second transistors M2_1 to M2_3. This allows costs to be reduced as compared to the comparative technique.

The present disclosure extends to various devices and methods that can be understood as the block diagram or circuit diagram of FIG. 1 or derived from the above description, and is not limited to a specific configuration. Hereinafter, more specific configuration examples or examples will be described not to narrow the scope of the present disclosure, but to facilitate understanding of the essence and operation of the present disclosure and to clarify the same.

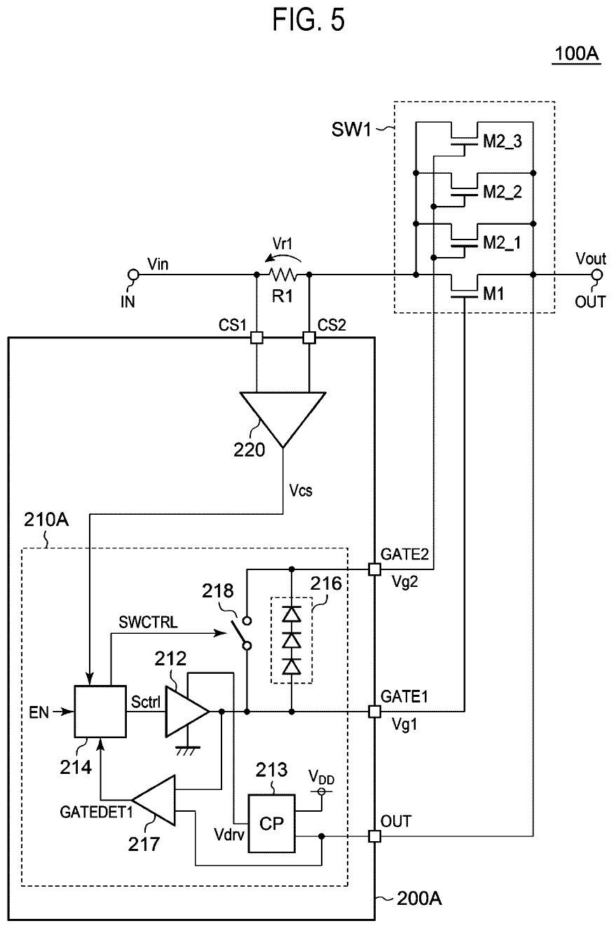

FIG. 5 is a circuit diagram of a circuit system 100A including a hot swap controller IC 200A according to an example. A gate controller 210A includes a gate driver 212, a charge pump circuit 213, a control circuit 214, a constant voltage circuit 216, a voltage detection circuit 217, and a switch 218.

The charge pump circuit 213 adds a constant voltage Vdd to the output voltage Vout to generate a voltage Vdrv to be applied to the gate of the switch SW1. This voltage Vdrv is supplied to the gate driver 212. The output voltage of the gate driver 212, i.e., the voltage level of the first gate voltage Vg1, is controlled by a control signal Sctrl generated by the control circuit 214.

The control circuit 214 is supplied with the current detection signal Vcs. The control circuit 214 may generate the control signal Sctrl so that the current I flowing through the switch SW1 becomes a target amount Iref. When the switch SW1 is turned on, the target amount Iref may be increased over time at a constant slope or according to an arbitrary waveform.

Alternatively, the control circuit 214 may generate the control signal Sctrl so that the power consumption P=I×Vds of the switch SW1 becomes a target amount Pref. When the switch SW1 is turned on, the target amount Pref may be increased over time at a constant slope or according to an arbitrary waveform.

Alternatively, the control circuit 214 may generate the control signal Sctrl so that the first gate voltage Vg1 increases at a constant slope or according to an arbitrary waveform.

The constant voltage circuit 216 is provided between the first gate terminal GATE1 and the second gate terminal GATE2, and keeps the potential difference ΔV therebetween constant. Therefore, the second gate voltage Vg2 generated at the second gate terminal GATE2 is expressed by the following equation, and the second gate voltage Vg2 rises with a delay while keeping the potential difference with the first gate voltage Vg1 constant.

Vg2=Vg1−ΔV

For example, the constant voltage circuit 216 may include one diode or a plurality of diodes connected in series.

The switch 218 is provided between the first gate terminal GATE1 and the second gate terminal GATE2. The voltage detection circuit 217 compares the gate-source voltage Vgs1=Vg1−Vout of the first transistor M1 with a predetermined threshold voltage Vth. When Vgs1>Vth, the voltage detection circuit 217 asserts a gate detection signal GATEDET1.

In response to the assertion of the gate detection signal GATEDET1, the control circuit 214 changes a control signal SWCTRL to an on level and turns on the switch 218.

The above is a configuration of the hot swap controller IC 200A.

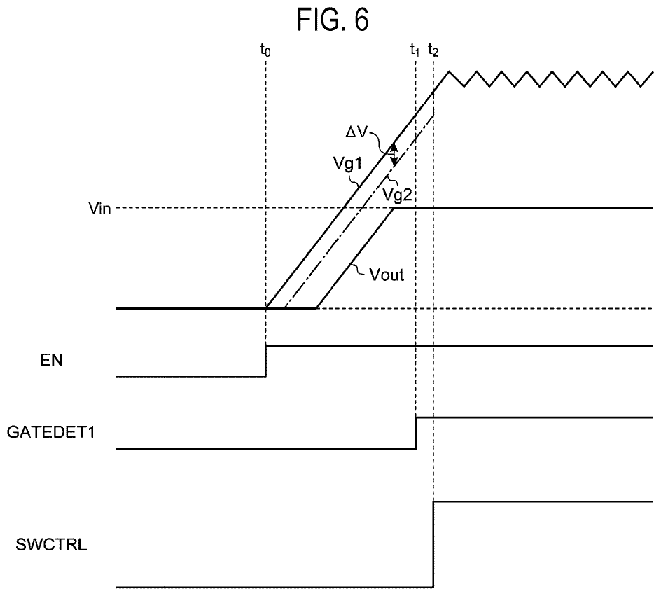

FIG. 6 is a waveform diagram for explaining an operation of the hot swap controller IC 200A of FIG. 5. When the enable signal EN is asserted at time t₀, the control circuit 214 generates the control signal Sctrl so that the switch SW1 is gradually turned on, and raises the first gate voltage Vg1. The second gate voltage Vg2 rises while keeping the potential difference ΔV with the first gate voltage Vg1 constant.

When the gate-source voltage Vgs1 of the first transistor M1 reaches the threshold voltage Vth at time t₁, the voltage detection circuit 217 asserts the gate detection signal GATEDET1. In response to the assertion of the gate detection signal GATEDET1, the control circuit 214 changes the control signal SWCTRL to the on level at time t₂. This turns on the switch 218, bypasses the constant voltage circuit 216, and raises the second gate voltage Vg2 to the same voltage level as the first gate voltage Vg1.

Next, a modification of the circuit system 100 will be described.

In the hot swap controller IC 200A of FIG. 5, the two gate voltages Vg1 and Vg2 are generated by a combination of the single gate driver 212 and the constant voltage circuit 216, but the present disclosure is not limited thereto. For example, two gate drivers may be provided, and two gate voltages Vg1 and Vg2 may be generated by inputting different control signals from the control circuit 214 to the two gate drivers, respectively.

The embodiments according to the present disclosure have been described by using specific terms, but this description is merely an example to aid understanding and does not limit the scope of the present disclosure or the claims, and the scope of the present disclosure is defined by the claims. Furthermore, not only the above-described embodiments, but also embodiments, examples, and modifications not described herein are included in the scope of the present disclosure.

### Supplementary Notes

The following techniques are disclosed in the present disclosure.

### Supplementary Note 1

A hot swap controller circuit that controls a plurality of transistors connected in parallel, including:
a first gate terminal to be connected to a gate of a first transistor having a widest safe operation area among the plurality of transistors;
a second gate terminal to be connected to a gate of a second transistor other than the first transistor among the plurality of transistors; and
a gate controller configured to control a voltage of the first gate terminal and a voltage of the second gate terminal,
wherein, when the plurality of transistors are turned on, the gate controller increases the voltage of the second gate terminal with a delay relative to the voltage of the first gate terminal.

### Supplementary Note 2

The hot swap controller circuit of Supplementary Note 1, wherein the gate controller increases the voltage of the first gate terminal and the voltage of the second gate terminal while keeping a potential difference between the voltage of the first gate terminal and the voltage of the second gate terminal constant.

### Supplementary Note 3

The hot swap controller circuit of Supplementary Note 2, wherein the gate controller includes:
a control circuit configured to generate a control signal;
a gate driver configured to generate a first gate voltage at the first gate terminal in response to the control signal; and
a constant voltage circuit connected between the first gate terminal and the second gate terminal.

### Supplementary Note 4

The hot swap controller circuit of Supplementary Note 3, wherein the constant voltage circuit includes one diode or a plurality of diodes connected in series.

### Supplementary Note 5

The hot swap controller circuit of Supplementary Note 3 or 4, wherein the control circuit generates the control signal so that a current flowing through the plurality of transistors is a target amount.

### Supplementary Note 6

The hot swap controller circuit of Supplementary Note 3 or 4, wherein the control circuit generates the control signal so that power consumption of the plurality of transistors is a target amount.

### Supplementary Note 7

The hot swap controller circuit of Supplementary Note 3 or 4, wherein the control circuit generates the control signal so that the first gate voltage changes according to a predetermined waveform.

### Supplementary Note 8

The hot swap controller circuit of any one of Supplementary Notes 1 to 7, wherein the gate controller includes:
a voltage detection circuit configured to assert a gate detection signal when a gate-source voltage of the first transistor exceeds a predetermined threshold voltage; and
a switch connected between the first gate terminal and the second gate terminal,
wherein the control circuit turns on the switch when the gate detection signal is asserted.

### Supplementary Note 9

The hot swap controller circuit of any one of Supplementary Notes 1 to 8, which is integrated on a single semiconductor substrate.

### Supplementary Note 10

A circuit system including:
a plurality of transistors connected in parallel; and
the hot swap controller circuit of any one of Supplementary Notes 1 to 6, which is configured to control the plurality of transistors.

### Supplementary Note 11

A circuit system comprising:
a first transistor connected between an input terminal and an output terminal and having a first safe operation area;
at least one second transistor connected in parallel with the first transistor between the input terminal and the output terminal and having a second safe operation area narrower than the first safe operation area; and
a hot swap controller circuit configured to control the first transistor and the at least one second transistor,
wherein the hot swap controller circuit turns on the at least one second transistor after the first transistor is turned on.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A hot swap controller circuit that controls a plurality of transistors connected in parallel, comprising:
a first gate terminal to be connected to a gate of a first transistor having a widest safe operation area among the plurality of transistors;
a second gate terminal to be connected to a gate of a second transistor other than the first transistor among the plurality of transistors; and
a gate controller configured to control a voltage of the first gate terminal and a voltage of the second gate terminal,
wherein, when the plurality of transistors are turned on, the gate controller controls the voltage of the first gate terminal and the voltage of the second gate terminal so that the first transistor is turned on before the second transistor is turned on.

2. The hot swap controller circuit of claim 1, wherein the gate controller increases the voltage of the first gate terminal and the voltage of the second gate terminal while keeping a potential difference between the voltage of the first gate terminal and the voltage of the second gate terminal constant.

3. The hot swap controller circuit of claim 2, wherein the gate controller includes:
a control circuit configured to generate a control signal;
a gate driver configured to generate a first gate voltage at the first gate terminal in response to the control signal; and
a constant voltage circuit connected between the first gate terminal and the second gate terminal.

4. The hot swap controller circuit of claim 3, wherein the constant voltage circuit includes one diode or a plurality of diodes connected in series.

5. The hot swap controller circuit of claim 3, wherein the control circuit generates the control signal so that a current flowing through the plurality of transistors is a target amount.

6. The hot swap controller circuit of claim 3, wherein the control circuit generates the control signal so that power consumption of the plurality of transistors is a target amount.

7. The hot swap controller circuit of claim 3, wherein the control circuit generates the control signal so that the first gate voltage changes according to a predetermined waveform.

8. The hot swap controller circuit of claim 1, wherein the gate controller includes:
a voltage detection circuit configured to assert a gate detection signal when a gate-source voltage of the first transistor exceeds a predetermined threshold voltage; and
a switch connected between the first gate terminal and the second gate terminal,
wherein the control circuit turns on the switch when the gate detection signal is asserted.

9. The hot swap controller circuit of claim 1, which is integrated on a single semiconductor substrate.

10. A circuit system comprising:
a plurality of transistors connected in parallel; and
the hot swap controller circuit of claim 1, which is configured to control the plurality of transistors.

11. A circuit system comprising:
a first transistor connected between an input terminal and an output terminal and having a first safe operation area;
at least one second transistor connected in parallel with the first transistor between the input terminal and the output terminal and having a second safe operation area narrower than the first safe operation area; and
a hot swap controller circuit configured to control the first transistor and the at least one second transistor,
wherein the hot swap controller circuit turns on the at least one second transistor after the first transistor is turned on.
